(19) United States
(12) Patent Application Publication
(10) Pub. No.: US 2017/0160214 A1
(43) Pub. Date: Jun. 8, 2017

(54) A METHOD FOR DETERMINING THE AMOUNT OF H2O IN A SAMPLE

(71) Applicant: NANONORD A/S, Alborg (DK)

(72) Inventor: Ole Nørgaard Jensen, Alborg (DK)

(21) Appl. No.: 15/316,383

(22) PCT Filed: Jun. 3, 2015
(86) PCT No.: PCT/DK2015/050141

§ 371 Date: Dec. 6, 2016

(30) Foreign Application Priority Data
Jun. 6, 2014 (DK) PA 2014 70339

(51) Int. Cl. G01N 24/08; G01R 33/44; G01R 33/46

(52) U.S. Cl. CPC G01N 24/082; G01R 33/4608; G01R 33/448

(57) ABSTRACT

The application relates to a method of determining an amount of H₂O in a sample, the method comprises performing at least one NMR measurement on the sample wherein the NMR measurement comprises applying the sample in an NMR spectrometer and performing a NMR reading of ¹⁷O nuclei in the sample, the reading comprises obtaining ¹⁷O NMR data and determine the amount of H₂O in a sample by correlating the ¹⁷O NMR data to calibration data. The application also relates to a system suitable for determination of an amount H₂O in a sample, the system comprises a NMR spectrometer configured for performing a ¹⁷O NMR reading of the sample to obtain ¹⁷O NMR data, and a computer comprising calibrating data for calibrating the ¹⁷O NMR data the computer being programmed to processing the ¹⁷O NMR data to determining the amount of H₂O in the sample.

### TECHNICAL FIELD

The invention relates to a method and a system for determining the amount of H₂O in a sample.

### BACKGROUND ART

Water content in different materials has been determined using several different types of methods. A very simple method of determining ‘free’ water in a sample is to weigh a sample and subjecting the sample to a drying process for evaporating all free water. Thereafter the amount of water can be determined by a simple subtraction. This standard method is only suitable for a few types of products and further it is very time consuming.

GB 2135059 describes determine the water content in fruit by using an electric resistance type water content meter. However, an electric resistance type water content meter requires a relatively large amount of water and is not suitable if the content becomes relatively low.

US 2009/0256562 describes a method of determining change of the amount of liquid water in a hydrocarbon stream using NMR to thereby determining hydrate formation. The method is based on the observance that hydrogen functional groups have different chemical shifts i.e. the relaxation of an excited ¹H nucleus (the nucleus of the isotope) will appear at different positions along the spectral band with only few ppm's separating the different functional groups. This however requires a NMR spectrometer with a very homogenous magnet. Such NMR magnets are generally very technically complex and expensive.

### DISCLOSURE OF INVENTION

The object of the invention is to provide a new method for determining the amount of H2O in a sample, which method is relatively low cost and reliable.

This object has been solved by the present invention as defined in the claims. The method or the system of the invention for determining the amount of H₂O in a sample and/or embodiments thereof have shown to have a large number of advantages which will be clear from the following description.

It should be emphasized that the term “comprises/comprising” when used herein is to be interpreted as an open term, i.e. it should be taken to specify the presence of specifically stated feature(s), such as element(s), unit(s), integer(s), step(s) component(s) and combination(s) thereof, but does not preclude the presence or addition of one or more other stated features.

Reference made to “one embodiment” or “an embodiment” means that a particular feature, structure, or characteristic described in connection with an embodiment is included in at least one embodiment of the subject matter disclosed. Thus, the appearance of the phrases “in one embodiment” or “in an embodiment” in various places throughout the specification is not necessarily referring to the same embodiment.

Further, the skilled person will understand that particular features, structures, or characteristics may be combined in any suitable manner within the scope of the invention as defined by the claims.

The term “substantially” should herein be taken to mean that ordinary product variances and tolerances are comprised.

The method of determining an amount of H₂O in a sample of the invention comprises performing at least one NMR measurement on the sample wherein the NMR measurement comprises applying the sample in an NMR spectrometer and performing a NMR reading of ¹⁷O nuclei in the sample, the reading comprises obtaining ¹⁷O NMR data and determine the amount of H₂O in a sample by correlating the ¹⁷O NMR data to calibration data.

The term “¹⁷O nucleus” or in plural “¹⁷O nuclei” denotes the nucleus/nuclei of the ¹⁷O isotope. The ¹⁷O isotope is a very low natural abundance compound i.e. about 0.0373%.

It has a quadropolar spin of 5/2. Further it has a rather broad signal which heretofore has been seen in an obstacle in obtaining a clear ¹⁷O signal.

Generally quadrupolar nuclei are much more difficult to determine than symmetric nuclei with spin ½ such as ¹H which is the most frequent nuclei used in NMR determinations. When exiting energy is added to quadrupolar nuclei in a magnetic field, their energies will split into multiple levels. Further splitting patterns can be seen in their coupling with other nuclei. The NMR signals of quadrupolar nuclear are usually wider than those of spin ½ nuclei due to rapid quadrupolar relaxation. The line width increases with the line-width factor that is related to the quadrupole moment of the nuclei, the size and the asymmetry of the component

Heretofore NMR reading of ¹⁷O nuclei has been used only in scientific studies usually requiring labelling of the ¹⁷O nuclei in order to have a sufficient and clear result. It has never been suggested to implement reading of ¹⁷O nuclei to perform quantitative determinations without labelling: It is believed that this is caused by the belief that the very low natural abundance together with the quadropolar spin would result in too low and spread signals to provide a quantitative determination. Further it has been believed that in order to obtain a reliable result very high magnetic field equipment which is both very costly and requires large space was required.

According to the invention, however, it has surprisingly been found that the NMR reading of ¹⁷O nuclei of a sample provides a very good basis for determining the H₂O amount of the sample with a very high accuracy and even using relatively low cost NMR spectrometer.

Spectrometers are well known in the art and based on the teaching herein relating to the requirement of the NMR spectrometer the skilled person will be able to obtain a spectrometer for use in the present invention. Examples of spectrometers are e.g. described in U.S. Pat. No. 6,310,480 and in U.S. Pat. No. 5,023,551.

A spectrometer comprises a unit for providing a permanent field e.g. a permanent magnet assembly as well as a transmitter and a receiver for transmitting and/or receiving RF frequency pulses/signals The RF receiver and RF transmitter are connected to an antenna or an array of RF antennae, which may be in the form of transceivers capable of both transmitting and receiving. The spectrometer further comprises at least one computing element, in the following referred to as a computer.

General background of NMR formation evaluation can be found, for example in U.S. Pat. No. 5,023,551.

A general background description of NMR measurement can be found in “NMR Logging Principles and Applications” by George R. Coates et al, Halliburton Energy Services, 1999. See in particular chapter 4. Although this document does not specifically describe the NMR determination of ¹⁷O isotope, the principle applied is similar.

Although ‘NMR measurement’ in the following often will be used in singular to describe the invention, it should be observed that the singular term ‘NMR measurement’ also includes a plurality of NMR measurements unless other is specified.

The terms ‘NMR reading’ and ‘NMR Measurement’ are used interchangeable

The amount of H₂O may be determined in a relative or a specific amount e.g. in mass or number of atoms e.t.c.

Preferably the method comprises quantitatively determination H₂O in the sample in form of number of oxygen atoms or number of H₂O molecules or as concentration thereof in relative form or mass or in any other quantitative unit.

Preferably the method comprises quantitatively determination H₂O in the sample where the ¹⁷O nuclei is unlabeled—i.e. the sample is not enriched to label ¹⁷O nuclei of the H₂O contained therein.

In an embodiment the method comprises quantitatively determination H₂O in vapor form in the sample.

In an embodiment the method comprises quantitatively determination H₂O in frozen form in the sample.

In an embodiment the method comprises quantitatively determination H₂O in liquid form in the sample.

Advantageously the NMR measurement comprises simultaneously subjecting the sample to a magnetic field B, and a plurality of pulses of radio frequency energy E (RF pulses) and receiving relaxation signals from the ¹⁷O nuclei.

After the radio frequency pulse or pulses has/have excited the nuclei, the nuclei will preferably be allowed to relaxation which will continue over a time called the acquisition time or relaxation time thereby preferably giving an NMR signal due to an oscillating voltage induced by the precession of the nuclear spin. This result in a decaying sine wave is termed free induction decay (FID) data. In an embodiment the relaxation signals comprises a free induction decay (FID) data.

Advantageously the pulse sequence called a cycle of pulse sequence is repeated a plurality of times in order to improve signal-to-noise (S/N), which increases as the square root of the number of cycles.

Advantageously the FID data is processed using methods well known in the art preferably including subjecting the FID data to a furrier transformation to provide a frequency domain spectrum also called the ppm band or spectral band. The frequency domain spectrum shows the intensity as a function of frequency where the frequency width per ppm depend on the spectrometer and the size of its magnetic field i.e. the higher Tesla the larger frequency bandwidth per ppm.

Generally prior art NMR spectrometers operates with a relative high magnetic field e.g. 10 or 15 Tesla or even higher in order to have a high sensitivity (signal to noise ratio scales with 2^{nd} power of the magnetic field) for example in connection with RF saddle coil. However in accordance with the present invention it has been found that a relatively low magnetic field e.g. with a closely coupled helical coil actually provides an even more accurate determination. By using such a relatively low magnetic field the NMR spectrometer becomes much cheaper and further the required size of the NMR spectrometer is highly reduced which makes is much simpler to e.g. use a transportable NMR spectrometer. The relatively small NMR spectrometer is advantageously transportable e.g. on wheels. Thereby the NMR spectrometer can be used e.g. by a food control to on the spot determine the water content in food e.g. at a production facility and/or in a food store.

In an embodiment the NMR spectrometer generates frequency domain spectra with a frequency width per ppm of about 300 Hz/ppm or less, such as about 200 Hz/ppm or less, preferably of about 150 Hz/ppm or less, more preferably of about 100 Hz/ppm or less or even about 70 Hz/ppm or less.

Advantageously the NMR measurement comprises simultaneously subjecting the sample to a magnetic field B, and an exciting RF pulse with frequencies selected to excite a nucleus of spin of at least a part of the ¹⁷O nuclei. Preferably the exciting RF pulse span over a band width (span over a frequency range) which is sufficient to excite ¹⁷O nuclei of the H₂O in a sample.

The exciting RF pulse advantageously provided by impressing a RF pulse or a train of pulses with a stationary or varying field band width (Hz) for a sufficient time to saturate the nuclei. The time of application of the pulse is called the pulse width (μs). It is generally known within the art of NMR measurements that the higher the field band width the lower pulse width is required. In the present invention it has been found that even when using a relatively low field band width, very reliable results of the water content are obtained.

In practice the higher the magnetic field the higher frequency range of the exciting RF pulse is required for fully excite the nuclei of the ¹⁷O isotope. However since a high magnetic field requires an expensive NMR spectroscope, it is desired to use a relatively low magnetic field.

Advantageously the frequency range of the exciting RF pulse spans over up to about 20 KHz, such as up to about 10 KHz. In an embodiment the frequency range of the exciting RF pulse spans over up even a lover frequency range e.g. up to about 5 KHz.

It has been found that the magnetic field B beneficially may be selected to be relatively low while surprisingly a high resolution with low noise can be obtained. In an embodiment the NMR reading is performed in a magnetic field of up to about 2.5 Tesla, such as from about 0.3 Tesla to about 1.5 Tesla. Due to this relatively low magnetic field the equipment for performing the NMR reading can be kept at a surprisingly low cost while simultaneously a high resolution can be obtained.

In an embodiment the NMR reading is performed in a magnetic field of less than about 2 Tesla. In an embodiment the NMR reading is performed in a magnetic field of less than about 1.5 Tesla

In an embodiment the magnetic field is generated by a permanent magnet, such as a neodymium magnet. Since permanent magnets with relatively low magnetic fields are generally not costly, this solution provides a low cost solution which for many applications may provide a sufficient low noise and highly reliable result.

In an embodiment the magnetic field is generated by an electromagnet, such as a solenoid magnet or other electromagnets which are usually applied in motors, generators, transformers, loudspeakers or similar equipment. Electromagnets of high strength e.g. electromagnets that can be applied for generating a field for NMR applications are often relatively expensive compared with permanent magnets however, the low magnetic electromagnet based solution is still much cheaper that magnets used in prior art high resolution NMR spectrometers. In an embodiment it may be beneficial to use an electromagnet arranged to be adjustable by adjusting the current in the coil of the electromagnet to a desired level.

In an embodiment the magnetic field is generated by a permanent magnet in combination with an electromagnet which advantageously is constructed for providing a pulsed magnetic field. The permanent magnet may advantageously be a 0.3-1.5 tesla magnet and the electromagnet may advantageously be constructed to add in a stationary, a varied or a pulsed fashion about 0.3-1 Tesla to the total magnetic field.

In an embodiment the NMR reading is performed in a pulsed magnetic field. By pulsing the magnetic field even more accurate determinations can be obtained because measurements at different field strength provides a tool for identifying noise which may accordingly be filtered of.

Advantageously the NMR reading is performed in a magnetic field with a standard deviation of the field over the sample volume of more than 10 ppm such as from about 100 ppm to 3000 ppm. Such magnetic field has been found to be suitable for ¹⁷O NMR readings.

In an embodiment of the invention the magnetic field in the measuring zone, i.e. the part where the sample to be measured on is located when the NMR measurement is performed, is preferably relatively spatially homogeneous and relatively temporally constant. However, in general it is difficult to provide that the magnetic field in the measuring zone is entirely homogenous and further for most magnetic fields, the field strength might drift or vary over time due to aging of the magnet, movement of metal objects near the magnet, and temperature fluctuations. In the present invention it has been found that minor inhomogeneity's of the magnetic field has not practical negative effect and in fact it is believed that minor inhomogeneity's of the magnetic field may in fact add to improve the accuracy of the NMR measurement all though at present it cannot be fully explained.

Drift and variations over time can be dealt with by controlling temperature and/or by applying a field lock such as it is generally known in the art.

Spatial in homogeneities of the magnetic field can be corrected for by a simple calibration or alternatively or simultaneously such spatial in homogeneities can be adjusted for by shim coils such as it is also known in the art. Such shim coils may e.g. be adjusted by the computer to maximize the homogeneity of the magnetic field.

In an embodiment of the invention the method comprises performing a plurality of NMR measurement at a selected magnetic field. Preferably the magnetic field is kept substantially stationary during the plurality of NMR measurements.

In an embodiment the method of the invention comprises regulating the temperature e.g. by maintaining the temperature at a selected value.

In an embodiment the method comprises performing the NMR reading at a fixed temperature.

In an embodiment the method of the invention comprises determining the temperature.

In an embodiment the method of the invention comprises performing the NMR readings at pulsed temperature.

In an embodiment the method comprises performing the NMR reading at temperature which is pulsed, preferably the pulsing range is from about 1° C. to about 90° C., such as from about 10° C. to about 80° C., such as from about 20° C. to about 70° C. The pulsed temperature may advantageously be applied for correlation of resulting measurements at different temperatures to eliminate errors and/or for improved pH determination as described above.

In an embodiment the NMR measurement comprises simultaneously subjecting the sample to a magnetic field B, and an exciting RF pulse with frequencies selected to excite the ¹⁷O nuclei of the H2O bound oxygen, preferably such that ¹⁷O nuclei of organic bound oxygen are substantially not excited.

According to the invention it has been found that due to the quadroplar nature of the ¹⁷O isotope the H₂O bound oxygen can be excited with an RF pulse only covering a central field band width frequency whereas ¹⁷O nucleus of organic bound oxygen are substantially not excited, because due to the quadroplar effects organic bound oxygen requires broader excitation field band width to be excited.

In an embodiment the exciting RF pulse with frequencies selected to excite the ¹⁷O nuclei of the H₂O bound oxygen is therefore a soft RF pulse having a field band width of up to about 1 KHz, such as from about 100 to about 500 Hz, such as from about 150 to about 300 Hz. Generally the term “soft RF pulse” mean herein a pulse having a field band width of up to about 1 KHz, the soft RF pule may have a stationary or varying field band. For relatively large and/or inhomogeneous samples it may be desired to pulse the field band or apply a train of soft RF pulses.

According to the invention it has been found to be very beneficial to determining an amount of H₂O in a sample, the method comprises performing at least one NMR measurement on the sample wherein the NMR measurement comprises applying the sample in an NMR spectrometer and performing a NMR reading of ¹⁷O nuclei in the sample, the reading comprises obtaining ¹⁷O NMR data and determine the amount of H₂O in a sample by correlating the ¹⁷O NMR data to calibration data, wherein the NMR measurement comprises simultaneously subjecting the sample to a magnetic field B, and an exciting soft RF pulse with frequencies selected to excite a nuclei of spin of at least a part of the ¹⁷O nuclei and wherein the soft RF pulse advantageously is less than about 500 Hz.

Advantageously the sample is subjected to a plurality of RF pulses and a plurality of NMR readings.

In an embodiment the sample is subjected to an exciting RF pulse with frequencies selected to excite substantially all nuclei spins of substantially all ¹⁷O isotopes in the sample.

In an embodiment the sample is subjected to an exciting soft RF pulse with frequencies selected to excite substantially all nuclei spins of substantially all the water bound ¹⁷O isotopes in the sample.

In an embodiment the method comprises transmitting narrow bandwidth pulses, such as with a bandwidth of from about 10 ppm to about 200 ppm, such as from about 30 ppm to about 300 ppm, to thereby stimulate the water bound ¹⁷O isotopes in the sample.

A sufficient frequency range of radio pulses can be found by performing a calibration test on a sample with known content of water, where the sample with know content of water preferably has a water content within about ±10% of the sample, such as within about ±10% of the sample.

In an embodiment the radio frequency pulses are in form of adiabatic RF pulses, i.e. RF pulses that are amplitude and frequency modulated pulses.

In an embodiment the method comprises subjecting the sample to pulsed trains of RF pulses, preferably with repetition rates of at about 400 ms or less, such as from about 10 to about 200 ms, such as from about 15 to about 20 ms.

In an embodiment the exciting RF pulse or train of pulses has a field band width (Hz), a pulse width (μs) and amplitude (Volt) selected to provide the desired angle pulse, such as a 45° pulse, a 90° or a 180° pulse, preferably the field band width of the pulse up to about 1 KHz, such as from about 100 to about 500 Hz, such as from about 150 to about 300 Hz.

The phrase “an X° pulse” where X can be any degree should be interpreted to include a train of X° pulses unless otherwise specified

In an embodiment the NMR measurement comprises simultaneously subjecting the sample to a magnetic field B, and a plurality of RF pulses wherein the RF pulses comprise a plurality of exciting RF pulses and a plurality of refocusing RF pulses.

Advantageously the exciting RF pulses are soft pulses having field band width of up to about 1 KHz, such as from about 100 to about 500 Hz, such as from about 150 to about 300 Hz.

In principle the refocusing RF pulses may have any have any field band width and often it is desired to apply refocusing RF pulses with a relatively high field band width in order to reduce the pulse width.

In an embodiment the method of the invention comprises determining at least one relaxation rate of the exited ¹⁷O nuclei in the sample.

In an embodiment the ¹⁷O NMR data comprises ¹⁷O T1 data and/or ¹⁷O T2 data.

The term relaxation describes processes by which nuclear magnetization excited to a non-equilibrium state return to the equilibrium distribution. In other words, relaxation describes how fast spins “forget” the direction in which they are oriented. Methods of measuring relaxation times T1 and T2 are well known in the art.

In an embodiment the method comprises determining at least one spin-lattice—T1 relaxation value of the exited ¹⁷O nuclei.

It is believed that T1 relaxation involves redistributing the populations of nuclear spin states in order to reach the thermal equilibrium distribution.

T1 relaxation values may be dependent on the NMR frequency applied for exciting the exited ¹⁷O nuclei. This should preferably be accounted for when analyzing and calibrating the T1 relaxation values obtained.

In an embodiment the method comprises determining at least one spin-spin—T2 relaxation value of the exited ¹⁷O nuclei. The T2 relaxation is also called the transverse relaxation. Generally T2 relaxation is a complex phenomenon and involves decoherence of transverse nuclear spin magnetization. T2 relaxation values are substantially not dependent on the magnetic field applied during excitation of the ¹⁷O nuclei, and for most determinations such possible variations can be ignored.

According to the invention it has been found that the T1 and/or T2 values for liquid water bound ¹⁷O and vapor water bound ¹⁷O differs and thereby this T1 and/or T2 data can be used to differ between liquid water bound ¹⁷O and vapor water bound ¹⁷O and ¹⁷O bound in other non-water compounds. The difference may depend on the type of sample and/or the temperature and accordingly the data may advantageously be calibrated by measurement of similar sample type with known content of liquid water and vapor.

In an embodiment the method comprises determination of the absolute water contents in volume or mass or molecule and in case the water is partly in form of vapor and partly in liquid form the amount of each is found using the T1 data and/or T2 data.

It has been found that the T1 data and T2 data also describe other properties of the water measured in the sample. For example the smaller the T1 and T2 values, the smaller are droplets or clusters of water i.e. the larger is the chemical interface between the water and non-water material.

In an embodiment the method comprises subjecting the sample to pulsed trains of RF pulses, such as soft RF pulses, preferably with repetition rates of at about 100 ms or less, such as from about 10 to about 50 ms, such as from about 15 to about 20 ms.

The trains of RF pulses may for example be applied to determine the T1 and/or T2 values.

In an embodiment, the method comprises subjecting the sample to trains of square RF pulses, preferably with repetition rates of about 100 ms or less, such as about 10 ms or less, such as about 5 ms or less, such as about 1 ms or less.

A short square pulse of a given “carrier” frequency “contains” a range of frequencies centered about the carrier frequency, with the range of excitation (bandwidth/frequency spectrum) being inversely proportional to the pulse duration.

A Fourier transform of an approximately square wave contains contributions from all the frequencies in the neighborhood of the principal frequency. The restricted range of the NMR frequencies made it relatively easy to use short (millisecond to microsecond) radio frequency pulses to excite the entire NMR spectrum.

In an embodiment the NMR measurement comprises simultaneously subjecting the sample to a magnetic field B and a plurality of RF pulses, preferably soft RF pulses, wherein the RF pulses comprise
i. an exciting RF pulse, and
ii. at least one refocusing RF pulse.

The exciting RF pulse and the refocusing pulse or pulses may for example be in the form of a train of RF pulses, e.g. pulsed pulses. The exciting RF pulse is preferably as described above and may in an embodiment be pulsed.

Useful duration and amplitude of the exciting RF pulses are well known in the art and optimization can be done by a simple trial and error.

In an embodiment the exciting RF pulse is in the form of a 90° pulse.

A 90° pulse is an RF pulse designed to rotate the net magnetization vector 90° from its initial direction in the rotating frame of reference. If the spins are initially aligned with the static magnetic field, this pulse produces transverse magnetization and free induction decay (FID).

In an embodiment the refocusing RF pulse(s) is in the form of a 180° pulse, preferably the method comprises subjecting the sample to a plurality of refocusing RF pulses, such as one or more trains of refocusing RF pulses.

A 90° pulse is an RF pulse designed to rotate the net magnetization vector 180° in the rotating frame of reference. Ideally, the amplitude of a 180° pulse multiplied by its duration is twice the amplitude of a 90° pulse multiplied by its duration. Each 180° pulse in the sequence (called a CPMG sequence after Carr-Purcell-Meiboom-Gill) creates an echo.

A standard technique for measuring the spin-spin relaxation time T2 utilizing CPMG sequence is as follows. As is well known after a wait time that precedes each pulse sequence, a 90-degree exciting pulse is emitted by an RF antenna, which causes the spins to start processing in the transverse plane. After a delay, an initial 180-degree pulse is emitted by the RF antenna. The initial 180-degree pulse causes the spins, which are dephasing in the transverse plane, to reverse direction and to refocus and subsequently cause an initial spin echo to appear. A second 180-degree refocusing pulse can be emitted by the RF antenna, which subsequently causes a second spin echo to appear. Thereafter, the RF antenna emits a series of 180-degree pulses separated by a short time delay. This series of 180-degree pulses repeatedly reverse the spins, causing a series of “spin echoes” to appear. The train of spin echoes is measured and processed to determine the spin-spin relaxation time T2.

In an embodiment the refocusing RF pulse(s) is/are applied with an echo-delay time after the exciting RF pulse. The echo-delay time (also called wait time TW) is preferably of about 500 μs or less, more preferably about 150 μs or less, such as in the range from about 50 μs to about 100 μs.

This method is generally called the “spin echo” method and was first described by Erwin Hahn in 1950. Further information can be found in Hahn, E. L. (1950). “Spin echoes”. Physical Review 80: 580-594, which is hereby incorporated by reference.

A typical echo-delay time is from about 10 μs to about 50 ms, preferably from about 50 μs to about 200 μs. The echo-delay time (also called wait time TW) is the time between the last CPMG 180° pulse and the first CPMG pulse of the next experiment at the same frequency. This time is the time during which magnetic polarization or T1 recovery takes place. It is also known as polarization time.

This basic spin echo method provides very good result for obtaining T1 relaxation values by varying TW and T2 relaxation values can also be obtained by using plurality of refocusing pulses.

The refocusing delay is also called the Echo Spacing and indicates the time identical to the time between adjacent echoes. In a CPMG sequence, the TE is also the time between 180° pulses.

This method is an improvement of the spin echo method by Hahn. This method was provided by Carr and Purcell and provides an improved determination of the T2 relaxation values which again allows for better quantitative determination of the isotope via more precise elimination of T2 effects via single or multi curve fitting for most precise envelope of spin echo amplitudes.

Further information about the Carr and Purcell method can be found in Carr, H. Y.; Purcell, E. M. (1954). “Effects of Diffusion on Free Precession in Nuclear Magnetic Resonance Experiments”. Physical Review 94: 630-638, which is hereby incorporated by reference.

There are several types of NMR measurements that depend on the introduction of a second irradiation frequency, i.e. irradiation of a nucleus other than the one being observed. In an embodiment the method of the invention comprises introduction of a second irradiation frequency irradiating of a nucleus other than the one being observed, such as ¹⁷O.

In an embodiment the NMR measurement comprises subjecting the sample to proton decoupling pulses and/or polarization pulses during at least a part of the NMR reading. This method has been found to increase the accuracy of the resulting H₂O determination.

In an embodiment the method comprising enhancing signal to noise of the data spectra by subjecting the sample to a pulse configuration providing a polarization and/or a proton decoupling of atoms of the H₂O in the sample.

In an embodiment the method comprising enhancing signal to noise of the data spectra by subjecting the sample to a pulse configuration comprising at least one of DEPT (Distortionless Enhancement by Polarization Transfer), DEPTQ (DEPT with retention of Quaternaries), HSQC (Heteronuclear Single Quantum Coherence), INEPT (Insensitive Nuclei Enhanced by Polarization Transfer), BIRD (Bilinear Rotation Decoupling pulses), TANGO (Testing for Adjacent Nuclei with a Gyration Operator) or NOE (Nuclear Overhauser Effect).

In an embodiment the method comprises subjecting the sample to a pulse configuration providing a polarization and or a proton decoupling of atoms of the H₂O in the sample and the method further comprises determine the pH value of the sample. Preferably the pulses are soft pulses.

In particular it has been found to be enhancing signal to noise of the data spectra by subjecting the sample to polarization treatment during the NMR reading, the polarization treatment preferably comprises DEPT (Distortionless Enhancement by Polarization Transfer) or NOE (Nuclear Overhauser Effect).

The Nuclear Overhauser Effect (NOE) is the transfer of nuclear spin polarization from one nuclear spin population to another via cross-relaxation. It is a common phenomenon observed by nuclear magnetic resonance (NMR) spectroscopy. Nuclear Overhauser Effect can for example be used to determine intra- (and even inter-) molecular distances. The NOE effect is the change in population of one proton (or other nucleus) when another magnetic nucleus close in space is saturated by decoupling or by a selective 180 degree pulse. Preferably the pulses used are soft pulses.

Further information about DEPT and NOE and how to perform them can e.g. be found in “New Method for NMR Signal Enhancement by Polarization Transfer, and Attached Nucleus Testing” by John Homer et al. J. Chem. Soc., Chem. Commun., 1994 and “Fundamentals of NMR” Chapter 1, by Thomas L. James, Department of Pharmaceutical Chemistry, University of California, 1998 (http://qudev.ethz.ch/content/courses/phys4/studentspresentations/nmr/James_Fundam entals_of_NMR.pdf)

In an embodiment the polarization treatment comprises subjecting the sample to cross polarization to thereby enhancing quantitative determination of relative amounts of two or more different ¹⁷O compounds or ions thereof, the cross polarization is preferably in form of DEPT.

In an embodiment the method comprising subjecting the sample to a pulse configuration comprising a) a DEPT-45 pulse sequence and b) a DEPT-90 pulse sequence and obtaining an NMR reading and a quantitative amount of excited ¹⁷O nuclei from each sequence wherein the quantitative amount of excited ¹⁷O nuclei by the DEPT-90 pulse sequence is subtracted from K1 times the quantitative amount of excited ¹⁷O nuclei by the DEPT-45 pulse sequence and the result is multiplied by K2 to thereby determine the amount of H₂O in the sample but specific excluding all OH groups from the result, wherein K1 is 1/sin(pi/2) and K2 is a constant determined by calibration on known samples comprising both organic and H2O bound oxygen. Other DEPT editing sequences may for example be used to exclude both H₃O and OH groups. The above described embodiment shows a very practical method when using small magnetic field which normally will be relatively inhomogeneous because all 3 groups OH, H₃O and H₂O deliver same phase in response and thereby do not cancel each other out. This is important when used in relative inhomogeneous magnet as frequency separation becomes impractical. Furthermore H₃O (Hydronomium) is not expected in large quantity except in very acid conditions.

The Heteronuclear Single Quantum Coherence (HSQC) or Heteronuclear Single Quantum Correlation (HETCOR) experiment is well known within the art of NMR spectroscopy of organic molecules and is of particular significance in the field of protein NMR analysis. The resulting spectrum is two-dimensional with one axis for ¹H and the other for another isotope in the present method ¹⁷O. The obtained spectrum contains a peak for each unique proton attached to the heteronucleus—here ¹⁷O. Further information about the general principle can be found in Bodenhausen, G.; Ruben, D. J. (1980. Chemical Physics Letters 69 (1): 185-189. By using the HSQC the method may further comprise determining pH value of the sample.

Insensitive Nuclei Enhanced by Polarization Transfer (INEPT) is a signal enhancement method used in NMR spectroscopy which involves the transfer of nuclear spin polarization from spins with large Boltzmann population differences to nuclear spins of interest with low Boltzmann population differences. INEPT uses J-coupling for the polarization transfer in contrast to Nuclear Overhauser Effect (NOE) which arises from dipolar cross-relaxation. See e.g. Gareth A. Morris, Ray Freeman (1979). “Enhancement of Nuclear Magnetic Resonance Signals by Polarization Transfer”. Journal of the American Chemical Society 101 (3): 760-762.

In principle the sample may have any suitable size which can fit into the measuring site of the NMR spectrometer. The measuring site of the NMR spectrometer is the site where the sample is arranged in the magnetic field and subjected to the RF pulses during the NMR reading.

The amount of H₂O in the sample is determined by a method comprising correlating the ¹⁷O NMR data to calibration data. The ¹⁷O NMR data may be used to calibrate the NMR apparatus and/or to directly process the obtained ¹⁷O NMR data. The ¹⁷O NMR data and optionally other NMR data is subjecting processing such that it is well known in the art preferably comprising furrier transformation, integration processes over intensity curves along the spectral band and determination of T1 and T2 data and using curve fitting algorithms on these for precise quantitative determination.

In an embodiment method comprises providing calibration data of samples with known amount of H₂O. The calibration data advantageously constitutes a calibration map. The calibration map comprises the desired NMR data and optionally additionally data such as data relating to temperature(s), pH value(s) and or relative amounts of selected components in dependence of pH value and/or temperature.

The term ‘calibrating map’ is herein used to designate a collection of NMR data obtained of samples with known amounts of H₂O and optionally other data which can be used in the interpretation of NMR data. The calibration map may be in form of raw data, in form of drawings, in form of graphs, in form of formulas or any combinations thereof. Advantageously the calibration data is stored in the computer of the NMR spectrometer and used by the computer in the processing of measured NMR data.

In an embodiment the calibration map is in the form of a pre-processed data set, where the NMR spectra obtained for a sample under analysis can be processed by the computer to provide a clear level, amount or concentration of H₂O in the sample.

In an embodiment the method comprises preparing calibration data and storing the calibration data on a digital memory preferably of the computer.

The calibration map may be built up during use, for example additional data obtained by measurement on the sample is fed to the computer and used in the calibration of the data for later determinations

The computer may for example be programmed to compute the data obtained using artificial intelligence or the calibration map may be applied to teach a neural network.

In an embodiment the sample size has a volume of at least about 0.1 cm³.

In an embodiment the sample size has a volume of at least about 1 cm³.

The size of the sample needs not being known. In an embodiment the sample size is known prior to the NMR reading. This may e.g. be useful if a dry matter determination is to be performed. When using fluid sample the sample size will usually be known.

In an embodiment the sample size is not known prior to the NMR reading. In this embodiment it may be desired to further using NMR to determine the sample size, Where other components of the sample is/are known e.g. if the sample is mainly a hydrocarbon/water sample, the total sample size may e.g. be determined by performing a NMR reading of ¹³C nuclei in the sample.

In an embodiment the method comprises performing at least one NMR measurement on the sample, preferably the method comprises performing a plurality of NMR measurements and optionally other measurements, such as ¹H NMR measurement, ¹³C NMR measurements, ³¹P NMR measurements and/or ³⁹K NMR measurements.

The ¹³C determination using NMR can be performed in a similar manner as the method described above but by using other frequencies and optionally the strength of the magnetic field may also be adjusted. The skilled person will know how to perform such determinations. In an embodiment the determination of carbon is performed using the same hardware (magnet, pulse emitter, receiver and similar) as used in the nitrogen ¹⁷O determination. Thereby the equipment and the set up can be economical feasible.

In an embodiment the method further comprising quantitatively determination of hydrocarbon containing components, preferably by subjecting the sample to an NMR reading in combination with cross polarization preferably in form of DEPT comprising generating a ¹³C data and correlating the ¹³C NMR data to calibration data.

In an embodiment the NMR spectrometer comprises a weight or mass meter for determining the weight and/or volume and/or mass of the sample.

The method of the invention has a plurality of application and may be used for determine the H₂O content in many different types of sample. In principle the method can be applied on any kind of sample which is penetrable by the RF pulses.

Examples of suitable samples comprise meat, meat powder, cheese, butter or corn, flour, skin, oil and wood.

In an embodiment the sample is flowable. This may be a liquid sample a gas sample of a pellets or powder or similar. In an embodiment NMR reading is performed on the sample in flowing condition or in semi flowing condition.

In an embodiment the NMR measurement is performed on the sample flowing condition in a pipe section pumping the sample from a first fluid reservoir e.g. a container and back to the same first fluid reservoir. In this embodiment the method can advantageously comprising continuously determination of the pH value e.g. during fermentation and/other treatment of the material from where the sample is withdrawn. Thereby the condition and the development of the material e.g. a foodstuff under fermentation may be determined.

In an embodiment the NMR measurement is performed on the sample in flowing condition in a pipe section pumping the sample from a first fluid reservoir to a second fluid reservoir.

When performing the NMR measurement on the sample in flowing condition it should advantageously be ensured that the velocity of the flowing sample is adjusted or kept such that the sample is within the spectrometer range for a sufficient time to perform the NMR measurement. Preferably the sample should remain within the measuring site during the relaxation time.

In an embodiment the NMR measurement is performed on the sample in semi flowing condition in a pipe section pumping the sample from a first fluid reservoir to a second fluid reservoir, wherein the flow of the sample is temporarily stopped during at least a part of the NMR reading, advantageously a preselected sample amount is pumped through the pipe section, followed by a temporarily flow stop where after the flowing of the sample is resumed.

In an embodiment the method comprises determining dry matter in the sample. The dry matter of the sample can be determined as being the non-H₂O of the sample. The dry matter is advantageously determined as the difference between 100% water and the actual determined amount of water.

As an example is sewage water where optimum processing of the sewage requires knowledge about the amount of ‘not-water’ in the sewage. Another example where dry matter is important and the method of the invention advantageously may be applied is flour or corn.

The method of the invention may advantageously be applied for sample of foodstuff.

In an embodiment the sample is a sample having a water content of less than about 50%. In an embodiment the sample is a sample having a water content of less than about 30%. %. In an embodiment the sample is a sample having a water content of less than about 20%. In an embodiment the sample is a sample having a water content of less than about 10%.

According to the invention it has been found that the method is very suitable for determine water content in biological material, such as food even with relatively low water content. When using soft pulses the amount of H₂O can be determined with very high accuracy even where the sample comprises organic bound O isotopes.

Examples from food production can be using the method for controlling maximum water allowed in produced cheese, butter or meat powder. In such cases it is of paramount importance to have a water contents as close to maximum specified limit as possible to avoid over drying (and spending energy) and at same time to maximize produced amount of goods.

The measurement of H₂O in foodstuff may advantageously be used in control of foodstuff to very fast determine if meat has been pumped with water, to determine pH in foodstuff and etc. The very fast determination can ensure that foodstuff that does not pass the test can immediately be removed from the shelf of a food store. Since the NMR spectrometer requires only a small magnetic field, the NMR spectrometer may be a transportable unit e.g. mounted with wheel for simple transportation. The amount of H₂O may accordingly be determined on the spot.

In an embodiment sample is an oil such as a fuel oil or a lubricant (also called lube).

The method of the invention may advantageously be applied on a lube sample to determine the amount of H₂O in the lube. Lube oils contaminated by water can potentially indicate leaks and/or condensing causing damage to the machinery being lubed. An example can be the azipod system or engine lube oil systems, another one being humidity condensing in the lube oil of a windmill.

Another example where the method of determining the amount of H₂O advantageously may be applied is in the determination of H₂O in fuel oils, such as biofuel, crude oil or heavy fuel oil. In these cases the water contents may be used to determine the relative amount not contributing to energy contents in the fuel.

This determination is in particular useful when the NMR system also measure carbon content by measure the ¹³C isotope and/or Hydrogen content by measure ¹H isotope because the Gross heating value in the fuel is given by Hydrogen (less amount of hydrogen bound water) to Carbon ratio.

In an embodiment the method further comprises performing a NMR reading of ¹³C nuclei in the sample and determine the amount of carbon in the sample.

In an embodiment the method further comprises performing a NMR reading of ¹H nuclei in the sample and determine the amount of hydrogen in the sample.

In an embodiment the sample is partly or fully in gas form.

The method may for example comprise determine the amount of H₂O in a hydrocarbon gas stream.

Water vapor may be of big interest to measure when the media is in gas form. One example is in relation to gas refinery process and by measuring water contents in the hydrocarbon gas streams. In this way catalyst performance or other parameters may be monitored.

In an embodiment the method comprises determine the amount of H₂O in two or three of liquid form, fluid form and gas form (vapor).

In an embodiment the method of the invention comprises determine the amount of H₂O in a wood sample, such as a wood sample withdrawn from a building which has been subjected to water damage e.g. due to flooding. By determine the amount of H₂O the degree of the damage can be determined very fast. By performing the H₂O determination using the method of the invention it may also be possibly to detect if the building has been attacked by fungus.

With simultaneously measuring other isotopes of relevance in the sample it is possible with NMR alone to give a relative part of the sample in mass that is water. In case it is a fluidic or fixed sample it is furthermore possible to measure the total weight of the sample and thereby delivering results of the amount of water in the sample in relation to the sample.

The invention also comprises a system suitable for determination of an amount H₂O in a sample as described above.

The system of the invention comprises a NMR spectrometer configured for performing a ¹⁷O NMR reading of the sample to obtain ¹⁷O NMR data, and a computer comprising calibrating data for calibrating the ¹⁷O NMR data the computer being programmed to processing the ¹⁷O NMR data to determining the amount of H₂O in the sample. The calibration data may be as described above. In an embodiment the computer comprises hardware and software and the calibration data is incorporated into the computer e.g. by being incorporated into the software of the computer.

The computer is preferably integrated with the NMR spectrometer. In an embodiment the computer is an external computer.

In an embodiment the calibration data is in form of mathematical algorithms. The calibration data is advantageously based on NMR data obtained on samples with known compositions preferably comprising known amount of H₂O. The calibration data advantageously constitutes a calibration map. The calibration map comprises the desired NMR data for ¹⁷O and optionally other isotopes to be detected and optionally additionally data such as data relating to temperature(s), pH value(s) and or relative amounts of selected components in dependence of pH value and/or temperature and/or pressure.

In an embodiment the computer is programmed to build up the calibration map during use such that for example additional data obtained by measurement by the NMR spectrometer is fed to the computer and incorporated into the calibration map.

In an embodiment the computer is programmed to compute the data obtained using artificial intelligence.

The spectrometer may be any NMR spectrometer suitable for use in the performing of the method of the invention. Advantageously the spectrometer is as described above. Preferably the magnet(s) of the spectrometer is as described above.

Preferably the one or more magnets arranged to generate the magnetic field are relatively small magnets with low magnetic force. By using such a relatively small/low force magnets the NMR spectrometer becomes much cheaper and further the required size of the NMR spectrometer is highly reduced which makes is much simpler to e.g. use a transportable NMR spectrometer.

Preferably the NMR spectrometer comprises one or more magnets arranged to generate a maximal magnetic field of up to about 2.5 Tesla, preferably of from 0.1 to 2 Tesla.

In an embodiment the NMR spectrometer comprises a permanent magnet, such as a neodymium magnet. Since permanent magnets are generally not costly, this solution provides a low cost solution which for many applications may provide a sufficient low noise and highly reliable result.

In an embodiment the NMR spectrometer comprises an electromagnet, such as a solenoid magnet. In an embodiment the NMR spectrometer comprises a permanent magnet in combination with an electromagnet which advantageously is constructed for providing an adjustable and/or a pulsed magnetic field.

In an embodiment the NMR spectrometer is mounted on a wheeled carrier.

In an embodiment the system is mounted on a wheeled carrier.

Any NMR spectrometer has a spectrometer frequency range which gives the maximal operation range of the spectrometer.

Advantageously the NMR spectrometer of the system has a spectrometer frequency range of up to about 20 MHz, such as from about 1-10 MHz.

In an embodiment the NMR spectrometer of the system has a spectrometer frequency range of about 7-10 MHz. A spectrometer frequency range of 10 MHz results in a domain spectra with a frequency width per ppm of about 70 Hz/ppm.

The system may comprise one, two or more computers, one, two or more spectrometers and/or one, two or more calibration maps. The system may preferably be in data communication with the internet e.g. for communication with other similar systems, for sending and/or receiving data. The system may preferably comprise at least one display and/or an operating keyboard as well as any other digital equipment usually connected to digital systems, e.g. printers.

The system is in an embodiment configured to perform NMR measurement on a fluid sample in flowing condition.

All features of the inventions including ranges and preferred ranges can be combined in various ways within the scope of the invention, unless there are specific reasons not to combine such features.

### BRIEF DESCRIPTION OF EXAMPLES AND DRAWINGS

The invention is being illustrated further below in connection with a few examples and embodiment and with reference to the drawings in which:

FIG. 1 shows a diagram over the relationships between carbon/hydrogen ratio and gross heating value and carbon atoms.

FIG. 2 is a schematic drawing of an embodiment of a system of the invention for determining the amount of H₂O in a sample.

FIG. 3 is a schematic drawing of another embodiment of a system of the invention for determining the amount of H₂O in a sample.

FIG. 4 show a spectra obtained in example 1.

FIG. 5 show the basics of the CPMG pulse sequence.

FIG. 6 shows the phase response relationship OH, H₂O and H₃O groups the sample is being exposed to a DEPT NMR pulse sequence.

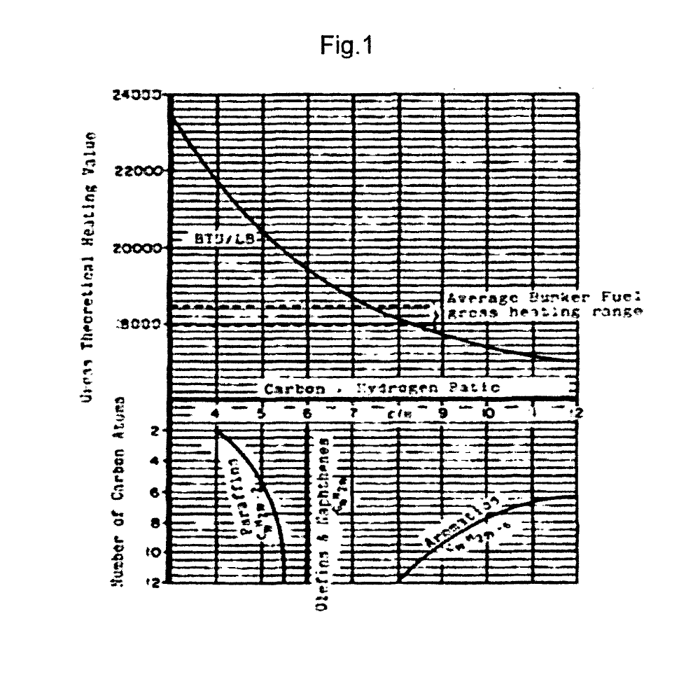

The diagram of FIG. 1 shows that there is a clear relationship between carbon/hydrogen ratio and gross heating value and carbon atoms in a fuel. This relationship is well known and is often applied to determine the gross heating value of a fuel and thereby to setting the value and price of the fuel. However the diagram does not take account of any possibly water in the fuel which results in a reduced heating value. By applying the method of the invention for determine the amount of H₂O in a fuel sample the amount of water bound hydrogen can be deducted to thereby find the gross heating value with an increased accuracy. Since the NMR spectrometer may simultaneously determine the carbon content and the hydrogen content as described above, the total gross heating value can be found in a simple and cost effective manner. In an embodiment of the system the computer is programmed to calculate the gross heating value based on the data of the diagram and the NMR readings on a fuel sample.

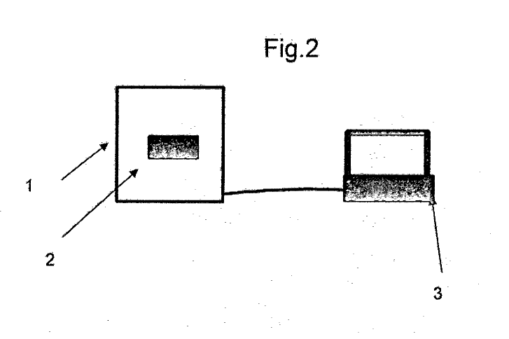

The system of for determining the amount of H₂O in a sample which is schematically shown in FIG. 2 comprises a NMR spectrometer 1 and an external computer 3 with a screen—here shown as a notebook connected to the NMR spectrometer 1. The NMR spectrometer 1 also comprises a not shown integrated computer. The calibration data may be contained in the notebook 3 or in the integrated computer or in both or partly in the notebook 3 and partly in the integrated computer. The measuring site of the NMR spectrometer 1 is indicated with the box 2. The system is advantageously connected to the internet as described above.

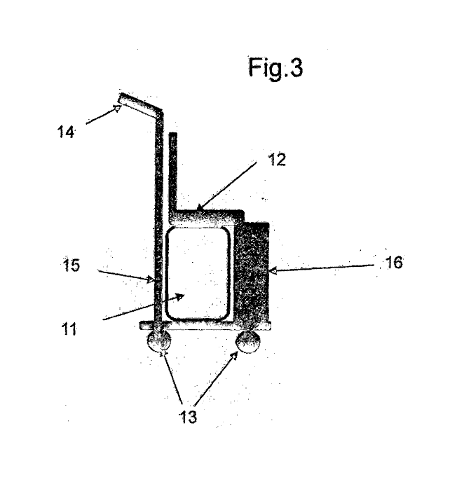

The system of for determining the amount of H₂O in a sample which is schematically shown in FIG. 3 is a wheeled system and comprises a NMR spectrometer 11 and an external computer 12 with a screen—here shown as a notebook connected to the NMR spectrometer 11. The NMR spectrometer 1 also comprises a not shown integrated computer. The calibration data may be contained in the notebook 12 or in the integrated computer or in both or partly in the notebook 12 and partly in the integrated computer. The system further comprises a printer 16. The NMR spectrometer 11, the notebook 12 and the printer 16 are arranged on a carrier 15 with wheels 13 and a handle 12. The notebook may 12 be detached from the carrier 15. The system is advantageously connected to the internet as described above.

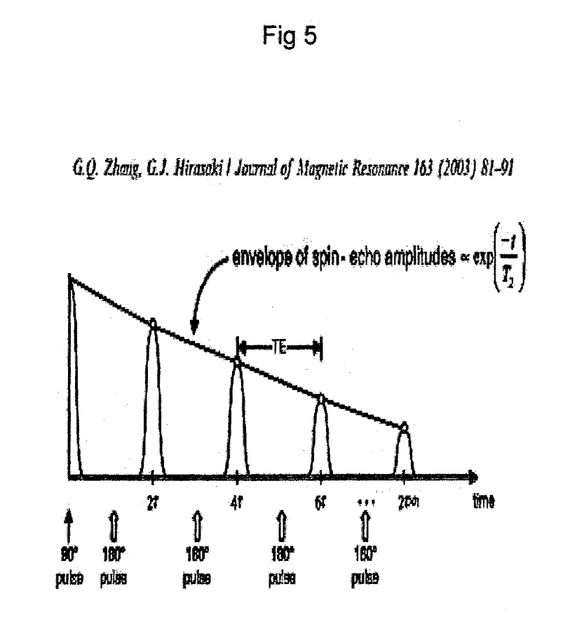

The CPMG pulse sequence is illustrated in FIG. 5. CPMG pulse sequence begins with a 90° pulse followed by a series of 180° pulses. The first two pulses are separated by a time period τ, whereas the remaining pulses are spaced 2τ apart. Echoes occur halfway between 180° pulses at 2τ, 4τ . . . 2nτ, where n is the echo number. TE stand for echo spanning and it equals to 2τ. Spin echo amplitudes are decaying with the time constant T₂.

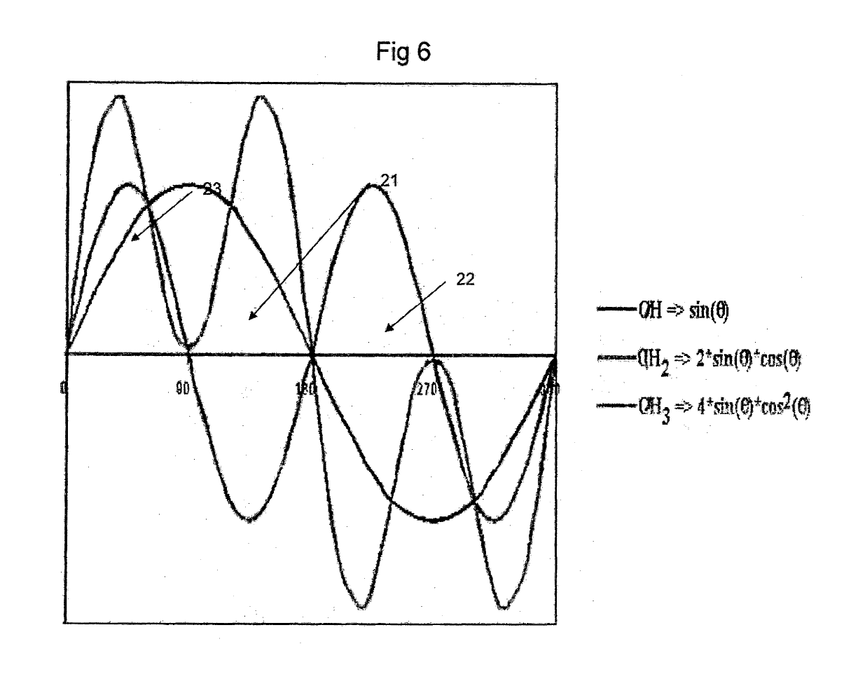

FIG. 6 shows the phase response relationship OH, H₂O and H₃O groups the sample is being exposed to a DEPT NMR pulse sequence where curve 20 is the OH curve, curve 21 is the H₂O curve and curve 22 is the H₃O.

### EXAMPLE 1

### Tap Water

A NMR spectrometer with spectrometer frequency range of about 8.71 was used. The magnetic field generated was about 1.5 Tesla and the domain spectra generated had a frequency width per ppm of about 73 Hz/ppm.

A tap water sample was acquired in an oblong sampling cuvette with an inner diameter of 8 mm. The cuvette was filled to a level of 100 mm and the sample was arranged in the measuring site of the spectrometer.

The sample was subjected to a plurality of ¹⁷O NMR readings by subjecting it to a plurality of cycles of a CPMG sequence of 40 times per second for 90 minutes. The pulse width for the 90° and 180° pulse was set to 25 μs. The echo delay was 150 μs and there were 24 echoes with 300 μs between each echo for each cycle.

The T2 was determined to be about 8 ms and T1 was determined to be several times larger than T2.

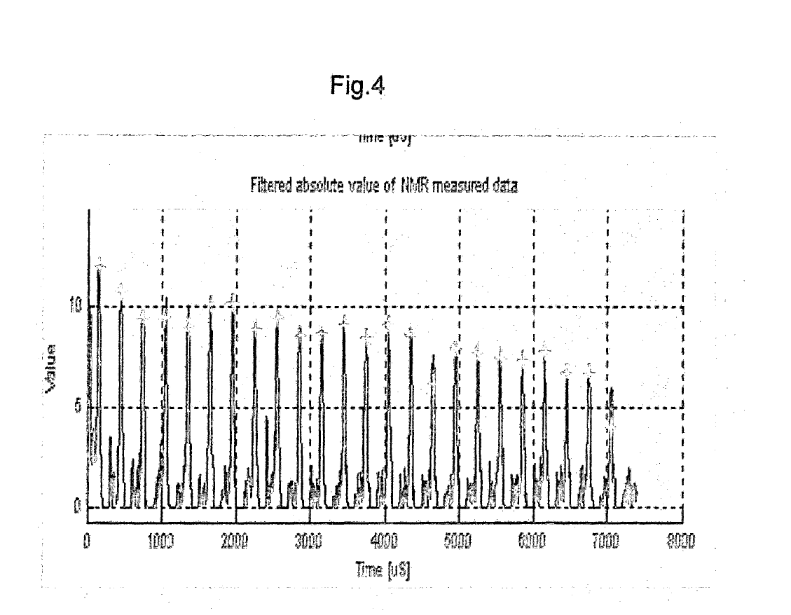

FIG. 4 show a spectra for the accumulated data and it can be seen that a clear and strong ¹⁷O signal was determined.

### EXAMPLE 2

### Meat Sample

The NMR spectrometer of example 1 is used.

A meat sample of about 2 cm³ (2×1×1) is arranged in the measuring site of the spectrometer.

The sample is subjected to a plurality of ¹⁷O NMR readings by subjecting it to a plurality of cycles of a CPMG sequence for about 2 minutes. The 90° pulses are soft pulses of about 1000 Hz and the 180° refocusing is set to a pulse width of 25 μs.

The obtained NMR data is processed to obtain a frequency domain spectrum ranging over about 500 ppm and the T1 and T2 is determined.

From the NMR data the water bound ¹⁷O is determined without signal from the organic bound oxygen and the total amount of H₂O in the meat sample is determined.

### EXAMPLE 3

### Sewage Sample

The NMR spectrometer of example 1 is used.

A sewage sample is arranged in an oblong sampling cuvette with an inner diameter of 8 mm. The cuvette is filled to a level of 100 mm and the sample is arranged in the measuring site of the spectrometer.

The sample is subjected to a plurality of ¹⁷O NMR readings by subjecting it to a plurality of cycles of a CPMG sequence for about 2 minutes followed by cycles of a DEPT sequence for 2 minutes. The 90° and the 45° pulses are soft pulses of about 300 Hz and the 180° refocusing is set to a pulse width of 25 μs.

The obtained NMR data is processed to obtain a frequency domain spectrum ranging over about 300 ppm and the T1 and T2 is determined.

From the NMR data the water bound ¹⁷O is determined and the total mass of H₂O in the sewage sample is determined and withdrawn from the total sewage sample mass to thereby determine the dry weight and the dry matter is determined as well.

### EXAMPLE 3

### Wood Sample

The NMR spectrometer of example 1 is used.

A wood sample of about 5 cm³ is obtained from a building which has been subjecting to flooding. The sample is arranged in the measuring site of the spectrometer.

The sample is subjected to a plurality of ¹⁷O NMR readings by subjecting it to a plurality of cycles of a CPMG sequence for about 10 minutes followed by cycles of a HSQC sequence for 10 minutes. The 90° and the 45° pulses are soft pulses of about 300 Hz and the 180° refocusing is set to a pulse width of 25 μs.

The obtained NMR data is processed to obtain a frequency domain spectrum ranging over about 300 ppm and the T1 and T2 is determined.

From the NMR data the water bound ¹⁷O is determined and the total mass of H₂O in the wood sample is determined and simultaneously the pH value is determined. By determine the amount of H₂O the degree of the damage can be determined very fast. The pH value may show if the building has been attacked by fungus.

1-41. (canceled)

42. A method of determining an amount of H₂O in a sample, the method comprising:
performing at least one NMR measurement on the sample wherein the NMR measurement comprises applying the sample in an NMR spectrometer;
performing a NMR reading in a magnetic field of up to about 2.5 Tesla of ¹⁷O nuclei in the sample, wherein the reading comprises obtaining ¹⁷O NMR data and
determining the amount of H₂O in a sample by correlating the ¹⁷O NMR data to calibration data.

43. The method of claim 42 wherein the NMR measurement comprises simultaneously subjecting the sample to said magnetic field B, and a plurality of pulses of radio frequency energy E (RF pulses) and receiving relaxation signals from the ¹⁷O nuclei, wherein the RF pulses has a band width of up to about 1 KHz.

44. The method of claim 42 wherein the RF pulses has a band width of up to about 500 Hz.

45. The method of claim 42, wherein the exciting RF pulse or train of pulses has a field band width (Hz) and a pulse width (μs) selected to provide the desired angle pulse selected from a 45° pulse, a 90° or a 180° pulse.

46. The method of claim 42, wherein the NMR measurement comprises simultaneously subjecting the sample to a magnetic field B, and a plurality of RF pulses, wherein the RF pulses comprise a plurality of exciting RF pulses and a plurality of refocusing RF pulses and the exciting RF pulses comprises at least one 90° pulse and the refocusing RF pulses comprises at least one 180° pulse.

47. The method of claim 42, wherein the NMR measurement comprises subjecting the sample to proton decoupling pulses and/or polarization pulses during at least a part of the NMR reading.

48. The method of claim 42, wherein the method comprising enhancing signal to noise of the data spectra by subjecting the sample to a pulse configuration providing polarization and/or proton decoupling of atoms of the H₂O in the sample.

49. The method of claim 42, wherein the method comprising enhancing signal to noise of the data spectra by subjecting the sample to a pulse configuration comprising at least one of DEPT (Distortionless Enhancement by Polarization Transfer), DEPTQ (DEPT with retention of Quaternaries), HSQC (Heteronuclear Single Quantum Coherence), INEPT (Insensitive Nuclei Enhanced by Polarization Transfer), BIRD (Bilinear Rotation Decoupling pulses), TANGO (Testing for Adjacent Nuclei with a Gyration Operator) or NOE (Nuclear Overhauser Effect).

50. The method of claim 49, wherein the method comprising subjecting the sample to a pulse configuration comprising a) a DEPT-45 pulse sequence and b) a DEPT-90 pulse sequence and obtaining an NMR reading and a quantitative amount of excited ¹⁷O nuclei from each sequence wherein the quantitative amount of excited ¹⁷O nuclei by the DEPT-90 pulse sequence is subtracted from K1 times the quantitative amount of excited ¹⁷O nuclei by the DEPT-45 pulse sequence and the result is multiplied by K2 to thereby determine the amount of H₂O in the sample, wherein K1 is fixed and K2 is a constant determined by calibration on known samples comprising both organic and H₂O bound oxygen.

51. The method of claim 42, wherein the method comprising subjecting the sample to a plurality of refocusing RF pulses comprising at least one train of refocusing RF pulses, wherein the refocusing RF pulse are applied with an echo-delay time of about 500 μs or less after the exciting RF pulse(s).

52. The method of claim 42, wherein the NMR reading is performed in a magnetic field of up to about 1.5 Tesla.

53. The method of claim 42, wherein the method comprises determining the amount of H₂O in a sample in form of a relative amount or in form of an absolute amount, wherein the sample size has a volume of at least about 1 mm³.

54. The method of claim 42, wherein the sample size has a volume of at least about 1 cm³.

55. The method of claim 42, wherein the sample is selected from meat, meat powder, cheese, butter or corn, flour, skin, oil or wood.

56. The method of claim 42, wherein the method comprises determining dry matter in the sample.

57. The method of claim 42, wherein the method further comprises performing a NMR reading of ¹³C nuclei in the sample and determine the amount of carbon in the sample.

58. The method of claim 42, wherein the method further comprises performing a NMR reading of ¹H nuclei in the sample and determine the amount of hydrogen in the sample.

59. The method of claim 58 wherein the method comprises determine the amount of H₂O in a hydrocarbon gas stream.

60. The method of claim 42 wherein the method comprises determine the amount of H₂O in two or three of liquid form, fluid form and gas form (vapor).

61. A system suitable for determination of an amount H₂O in a sample according to claim 1, the system comprises a NMR spectrometer configured for performing a ¹⁷O NMR reading of the sample to obtain ¹⁷O NMR data, and a computer comprising calibrating data for calibrating the ¹⁷O NMR data the computer being programmed to processing the ¹⁷O NMR data to determining the amount of H₂O in the sample wherein the NMR spectrometer comprises one or more magnets arranged to generate a magnetic field of up to about 2.5 Tesla.
